(19) United States
(12) Patent Application Publication
(10) Pub. No.: US 2025/0364332 A1
(43) Pub. Date: Nov. 27, 2025

(54) METHOD FOR MANUFACTURING ENGINEERED GROWTH SUBSTRATE FOR GROUP III NITRIDE POWER DEVICE HAVING HIGH-QUALITY NUCLEATION REGION

(71) Applicant: WAVELORD CO., LTD., Gyeonggi-do (KR)

(72) Inventor: June O SONG, Gyeonggi-do (KR)

(21) Appl. No.: 19/216,205

(22) Filed: May 22, 2025

(30) Foreign Application Priority Data
May 23, 2024 (KR) 10-2024-0066908

(51) Int. Cl. H01L 21/78

(52) U.S. Cl. CPC H01L 21/7813

(57) ABSTRACT

The present disclosure provides a method for manufacturing an engineered growth substrate for a group III-nitride power device in which a nucleation region is formed, comprising: a seed substrate preparation step of preparing a seed substrate made of single crystal SiC having a set thickness; a nucleation region forming step of forming a nucleation region on an upper surface of the seed substrate; a seed substrate reforming step of irradiating the seed substrate with a stealth laser to form a reforming layer parallel to the nucleation region inside the seed substrate; a temporary substrate bonding step of bonding a temporary substrate to an upper surface of the nucleation region using a predetermined adhesive layer after the seed substrate reforming step; and a seed region separation step of separating the seed region on which the nucleation region is formed from the seed substrate with the reforming layer as a boundary.

### CROSS-REFERENCE TO RELATED APPLICATIONS

This application claims priority to Korean Patent Application No. 10-2024-0066908, filed on 23 May 2025. The entire disclosure of the applications identified in this paragraph is incorporated herein by reference.

### FIELD

The present invention relates to a method for manufacturing an engineered growth substrate for a group III nitride power device having a high-quality nucleation region formed thereon, and more particularly, to a method for manufacturing an engineered growth substrate for a group III nitride power device having a composite material laminated structure having a nucleation region formed thereon and having high-quality film quality despite a thin growth substrate (seed region).

### BACKGROUND

Wafers for group Ill nitride semiconductor growth use single-material growth substrates.

It is difficult for a single-material growth substrate to simultaneously satisfy crystal defect density, surface polarity, device structure thickness, heat dissipation capacity, and cost.

Alternatively, an engineered growth substrate having a composite material layered structure made of different materials has been introduced as wafer for growing Group 3 Nitride Semiconductors.

An engineered growth substrate with a composite material laminated structure have a structure in which a thin seed region (layer), a bonding layer, and a support substrate are laminated.

Group III nitride semiconductors are grown on the seed region (layer).

The support substrate and bonding layer are intended to provide physical rigidity and stability to the group Ill nitride semiconductors.

An engineered growth substrate having a composite material laminated structure has a structure in which a thin seed region (layer) is firmly supported by a support substrate and a bonding layer from the lower side. Therefore, by using a thin seed region (layer), the cost can be reduced, and since group III-nitride semiconductors are deposited on top of the seed region (layer) with the same and similar equivalent physical properties (lattice constant), it can have quality characteristics superior to those of a single-material growth substrate.

However, an engineered growth substrate having a composite material laminated structure has limitations in terms of process when used as growth substrate for high-quality growth of the group III nitride semiconductors for group III nitride power device.

Specifically, the quality of semiconductors for group III nitride power devices is greatly affected by the quality of the nucleation region grown on the growth substrate (specifically, the seed region (layer)).

Prior to forming group III nitride semiconductors on top of a seed region (layer), a nucleation region is basically grown. At this time, the thickness uniformity and crystal defect density of the nucleation region have a significant impact on the performance and quality of group III nitride semiconductors formed on the seed region (layer), as well as on the reliability, lifespan, and yield.

Especially in power semiconductors such as HEMTs, MOSFETs, and JFETs that are applied with large currents of several to tens of amperes (A) or high voltages of hundreds to thousands of volts (V), a single fatal crystal defect can affect the lifespan or reliability.

In addition, if the thickness uniformity of the nucleation region is not good, the physical properties of group III nitride semiconductors for power device deteriorate, which has a significant impact on the performance and yield of the power device. Therefore, the growth of the nucleation region on the seed region (layer) must be managed simultaneously in terms of improving the thickness uniformity and minimizing the density of crystal defects.

The representative crystal defects that have a critical impact on group III nitride power devices are threading dislocations, inversion domains (IDs), and inversion domain boundaries (IDBs) of various types and characteristics.

Minimizing the density of crystal defects requires that the growth temperature of the nucleation region be high. On the other hand, to ensure uniformity in the thickness of the nucleation region, it is necessary to either lower the growth temperature of the nucleation region or increase the thickness of the engineered growth substrate to prevent bowing of the engineered growth substrate.

Increasing the thickness of the seed region (layer) that constitutes the engineered growth substrate is in conflict with the reason for adopting the engineered growth substrate.

In addition, the relatively thick seed region (layer) is subject to a lot of thermo-mechanical stress depending on the properties of the bonded support substrate and the growth temperature.

Therefore, the process technology that minimizes the crystal defect density of the nucleation region while growing at high temperatures on the relatively thick seed region (layer) and simultaneously maximizes the thickness uniformity of the nucleation region has been an issue that has faced considerable difficulties.

### SUMMARY

### Technical Problem

The present invention provides a method for manufacturing a SiC power semiconductor device, which can solve the high cost issue of a SiC growth substrate through a hot self-split process while applying a SiC growth substrate for a high-quality and high-performance SiC power semiconductor.

The present invention provides a method for manufacturing an engineered growth substrate for a group Ill nitride power device, in which a nucleation region has already been formed, having a film quality that is significantly improved over that which can be expected from a nucleation region directly grown on an engineered growth substrate of a composite material laminated structure (seed region (layer)-bonding layer-support substrate).

### Technical Solution

Embodiments according to the present invention provide a method for manufacturing an engineered growth substrate for a group III-nitride power device in which a nucleation region is formed, comprising: a seed substrate preparation step (S100) of preparing a seed substrate made of single crystal SiC having a set thickness; a nucleation region forming step (S200) of forming a nucleation region on an upper surface of the seed substrate; a seed substrate reforming step (S300) of irradiating the seed substrate with a stealth laser to form a reforming layer parallel to the nucleation region inside the seed substrate; a temporary substrate bonding step (S400) of bonding a temporary substrate to an upper surface of the nucleation region using a predetermined adhesive layer after the seed substrate reforming step (S300); and a seed region separation step (S500) of separating the seed region (layer) on which the nucleation region is formed from the seed substrate with the reforming layer as a boundary.

In embodiments according to the present invention, the method comprises a wafer bonding step (S700) of bonding a support substrate to a surface opposite to a surface on which the nucleation region is formed among both sides of the seed region (layer) separated by the seed region separation step (S500) via a predetermined wafer bonding layer; and a temporary substrate removing step (S800) of separating the temporary substrate from the nucleation region.

In embodiments according to the present invention, the method comprises a step (S600) of flattening the surface of the seed region (layer) on which the support substrate is bonded before the wafer bonding step (S700).

In embodiments according to the present invention, the seed region separation step (S40) is characterized in that both sides bordering the reforming layer are separated without an external force due to a structural asymmetry including a quantitative difference in thermal characteristics including a thermal expansion coefficient or a thickness difference.

### Advantageous Effects

According to the present invention, high-quality growth of a semiconductor layer for a group III nitride power device is possible using an engineered growth substrate having a nucleation region with excellent film formation quality in terms of thickness uniformity and crystal defect density minimization.

According to the present invention, an engineered growth substrate having a nucleation region with excellent quality in terms of thickness uniformity and crystal defect density can be obtained. Therefore, the disadvantages of the nucleation region grown on an engineered growth substrate of a conventional composite material laminate structure can be improved.

According to the present invention, by growing a high-quality nucleation region on a thick seed substrate and separating the seed region (layer) together with the nucleation region from the seed substrate to manufacture an engineered growth substrate, the thick seed substrate can be separated into a plurality of seed regions (layers) and used. Therefore, excellent quality of the nucleation region is secured, and a groundbreaking cost reduction is possible.

According to the present invention, by utilizing the quantitative difference in thermal characteristics including the thermal expansion coefficient between the seed region (layer) and the seed substrate or the structural asymmetry including the thickness difference, the seed region (layer) in which the nucleation region is formed is separated from the thick seed substrate, so that the separation can be achieved by minimizing the external force.

### BRIEF DESCRIPTION OF DRAWINGS

FIG. 1 is a drawing showing one embodiment of an engineered growth substrate for a group III nitride power device having a high-quality nucleation region formed.

FIGS. 2, 3, 4, 5, 6, 7, 8 and 9 are drawings showing one embodiment of a method for manufacturing an engineered growth substrate for a group Ill nitride power device having a high-quality nucleation region formed according to the present invention.

### DETAILED DESCRIPTION

Hereinafter, a method for manufacturing an engineered growth substrate for a group Ill nitride power device having a high-quality nucleation region formed according to embodiments of the present invention will be described in detail with reference to the drawings.

The terms used below have been selected for convenience of explanation, and should be appropriately interpreted in a meaning that is consistent with the technical idea of the present invention without being limited to the dictionary meaning.

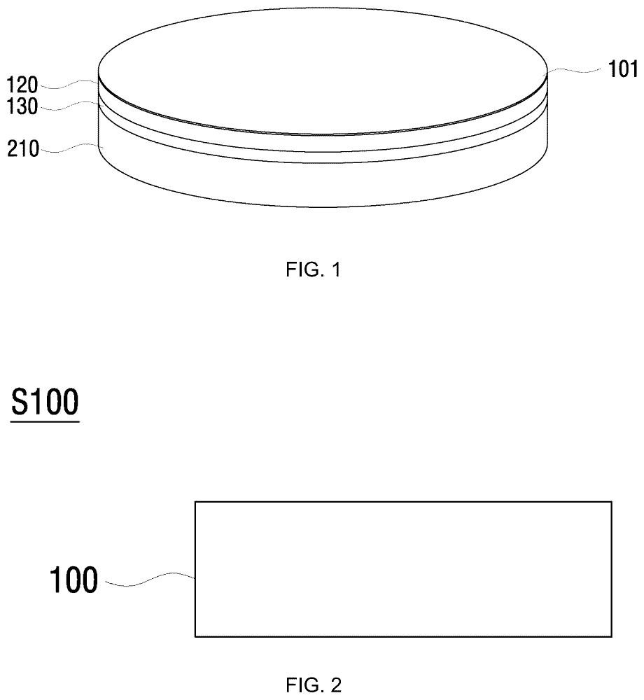

FIG. 1 is a drawing showing an embodiment of an engineered growth substrate for a group III nitride power device having a high-quality nucleation region formed.

Referring to FIG. 1, an engineered growth substrate for a group III nitride power device having a high-quality nucleation region formed according to the present embodiment comprises a support substrate (210), a seed region (layer) (120), and a nucleation region (101).

The support substrate (210) is for structurally supporting the seed region (layer) (120) and the nucleation region (101).

In the case where the seed region (layer) (120) is formed of single crystal SiC and the nucleation region (101) is formed of epitaxial AlN, it is preferable that the support substrate (210) is formed of any one of single crystal Si, single crystal SiC, polycrystalline AlN ceramic, and polycrystalline SiC ceramic.

Furthermore, it is preferable that the support substrate (210) is selected as a material whose thermal expansion coefficient difference from that of the seed region (layer) is zero or minimized in order to minimize the influence of thermo-mechanical stress during the growth process of the subsequent III-nitride semiconductors (device structure).

The support substrate (210) is preferably formed with a thickness of 500 to 1,000 μm for structural support.

The seed region (layer) (120) is arranged to be bonded to the support substrate (210) and is formed with a thickness of 50 to 200 μm.

When the seed region (layer) (120) is provided for the growth of a group III nitride power device, the seed region (layer) (120) is preferably formed with a thickness of 100 to 200 μm.

The bonding of the seed region (layer) (120) and the support substrate (210) is preferably a permanent bonding and is formed by a predetermined wafer bonding material. The wafer bonding layer can be formed with a thickness of 1 to 10 μm.

The nucleation region (101) is epitaxially grown on the seed region (layer) (120) and formed as epitaxial AlN.

The present invention is characterized in that, instead of directly growing a nucleation region (101) on a seed region (layer) (120) through epitaxy, a nucleation region (101) is epitaxially grown on a seed substrate (100) having a thickness that is at least twice the thickness of the seed region (layer) (120), and then the seed region (layer) (120) on which the nucleation region (101) is formed is separated from the seed substrate (100).

Accordingly, the film quality of the nucleation region (101) of the present invention is the same as the film quality of the nucleation region (101) epitaxially grown under the same growth conditions on a seed substrate (100) having a thickness that is at least twice the thickness of the seed region (layer) (120).

This film quality is dramatically improved compared to the film quality of the nucleation region (101) grown directly on the seed region (layer) (120).

The film quality refers to the thickness uniformity and/or crystal defect density, and the crystal defect density includes the Inversion Domain (ID) and the Inversion Domain Boundary (IDB).

ID refers to the region where the arrangement of the grown atoms is inverted (i.e., the N polar face region existing on the Al polar face or vice versa), and IDB refers to the boundary between the inverted portion of the grown atoms and the normal portion.

Therefore, a higher density of threading dislocations, IDs and IDBs means greater crystal defects.

When forming a nucleation region with AlN, a film can be deposited at a growth temperature of 1,200° C. or higher to secure much better quality. However, the higher the growth temperature, the greater the bowing of the growth substrate, making it difficult to secure thickness uniformity.

To solve this problem, the inventor of the present invention has developed a method of growing an AlN nucleation region (101) using a thick seed substrate (100), and then separating the seed region (layer) (120) and the AlN nucleation region (101) from the seed substrate (100).

Specifically, the seed region (layer) (120) on which the nucleation region (101) has grown is formed by slicing from the seed substrate (100) using the method described below. In addition, the seed substrate (100) from which the seed region (layer) (120) has been separated is reused by repeating the growth and slicing of the nucleation region.

As a result, the consumption of the relatively expensive seed substrate is minimized, while securing excellent film quality of the nucleation region (101).

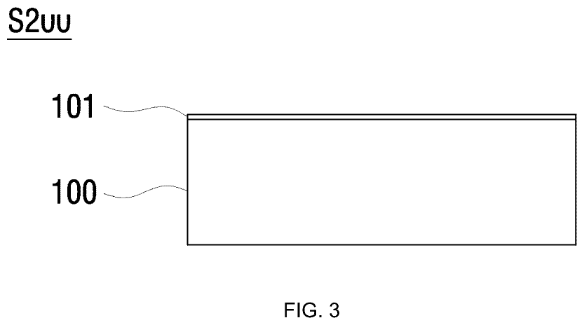

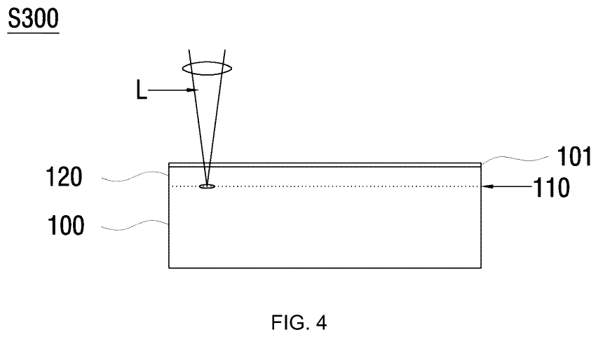

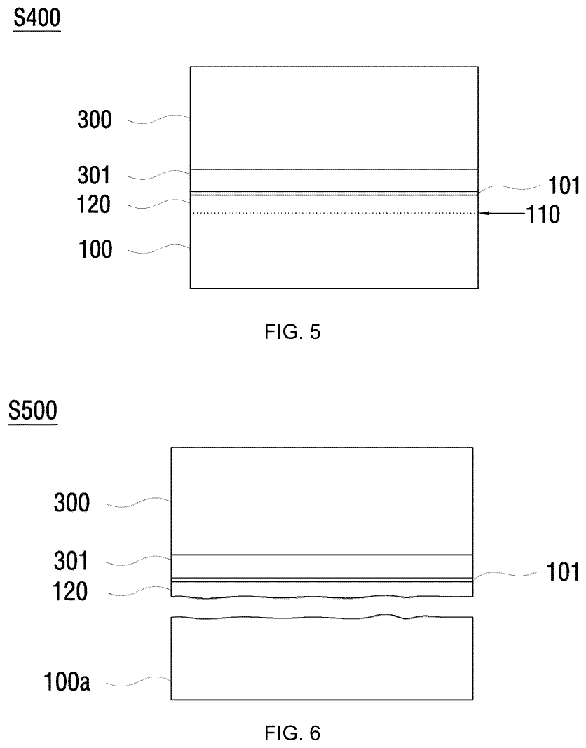

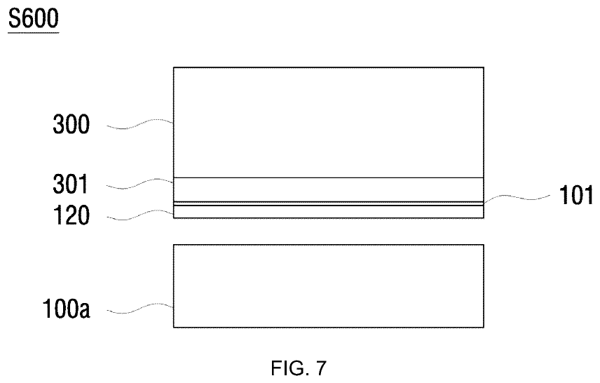

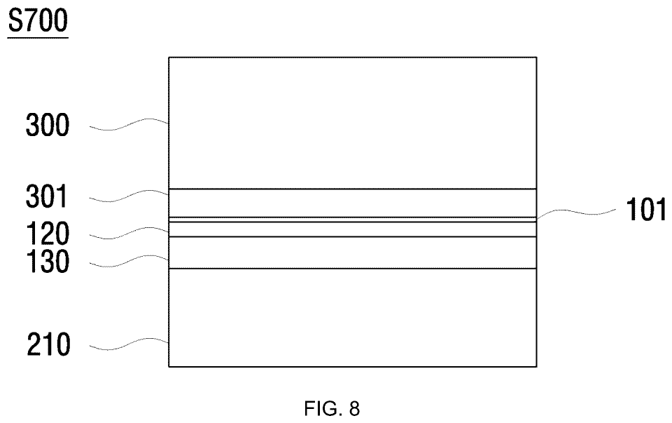

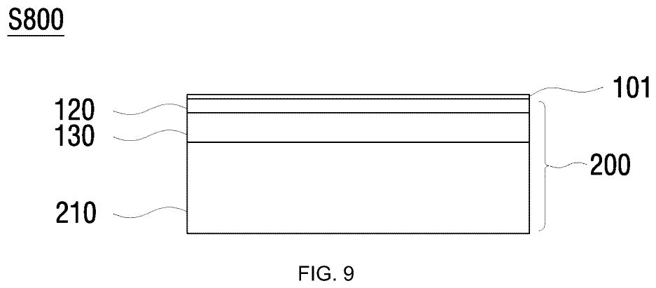

FIGS. 2 to 9 are drawings showing one embodiment of a method for manufacturing an engineered growth substrate for a group III nitride power device having a high-quality nucleation region formed according to the present invention.

Referring to FIGS. 2 to 9, the method for manufacturing an engineered growth substrate for a group III nitride power device having a nucleation region formed according to the present embodiment comprises a seed substrate preparation step (S100), a nucleation region forming step (S200), a seed substrate reforming step (S300), a temporary substrate bonding step (S400), and a seed region separation step (S500).

The seed substrate preparation step (S100) is a step of preparing a seed substrate (100) made of single crystal SiC having a set thickness.

It is preferable that the set thickness of the seed substrate (100) be at least twice the thickness of the seed region (layer) (120).

For example, the thickness of the seed substrate (100) may be at least 500 μm for 4 inches and 6 inches, and at least 750 μm for 8 inches, based on its diameter.

According to this, it is possible to secure uniform thickness of the nucleation region (101) and high-quality film quality.

Specifically, AlN used as a nucleation region material can secure much better film quality (minimization of crystal defects) by forming a film at a growth temperature of 1,200° C. or higher. However, the higher the growth temperature, the greater the bowing of the wafer, making it difficult to secure thickness uniformity.

To solve this problem, AlN, the material of the nucleation region (101), is grown at a growth temperature of 1,200° C. or higher by using a thick seed substrate (100) to prevent wafer bowing and secure thickness uniformity, and at the same time, high-quality film formation quality can be obtained by growing the film at a growth temperature of 1,200° C. or higher.

Furthermore, since the device structure (e.g., in GaN HEMT, a buffer layer, a channel layer, a barrier layer, and a cap layer) grown in the nucleation region (101) is grown at a temperature (around 1,000° C.) lower than the growth temperature of the nucleation region (101), the low crystal defects and thickness uniformity of the nucleation region (101) can ensure high quality of the subsequently grown device structure.

Meanwhile, for excellent film quality of the nucleation region (101), it is preferable that a positive or negative pattern be formed on the growth surface of the seed substrate (100) on which the nucleation region (101) is grown. According to this, the ELOG growth of the nucleation region (101) can be easily guided.

The nucleation region forming step (S200) is a step of forming a nucleation region (101) on the upper surface of the seed substrate (100). The nucleation region (101) is composed of an epitaxial AlN.

The seed substrate reforming step (S300) is a step of forming a reforming layer (110) parallel to the nucleation region inside the seed substrate (100) by irradiating the seed substrate (100) with a stealth laser.

The stealth laser (L) is a laser (Light Amplification by Stimulated Emission of Radiation) of a wavelength that can penetrate the seed substrate (100) or nucleation region (101), and forms a focal point at a specific point inside the seed substrate (100) using an optical system.

At the focal point where the photons of the stealth laser (L) are concentrated, a large number of bonds between the constituent atoms are destroyed, and at this time, when the focal point where the photons of the stealth laser (L) are concentrated moves along a specific plane to form a scanning plane, the reforming layer (110) is formed along the scanning plane.

It is preferable that the reforming layer (110) be formed at a depth corresponding to the thickness of the seed region (layer) (120) from the upper surface of the seed substrate (100) where the nucleation region (101) is formed.

It is preferable to irradiate the stealth laser (L) along a short path from both sides of the seed substrate (100) to the reforming layer (110), but it may also be irradiated along a relatively long path.

The temporary substrate bonding step (S400) is a step of bonding a temporary substrate (300) to the upper surface of the nucleation region (101) via a predetermined adhesive layer (301) after the seed substrate reforming step (S300) is performed as the first wafer bonding. Prior to forming the adhesive layer (301), a protective film may be formed using a predetermined material to protect the nucleation region (101).

The seed region separation step (S500) is a step of separating the seed region (layer) (120) in which the nucleation region (101) is formed from the seed substrate (100) with the reforming layer (110) as the boundary.

The seed region separation step (S500) is performed without external force during the process of cooling the heat applied in the temporary substrate bonding step (S400).

The two sides (100a vs. 120/101/301/300) with the reforming layer (110) as the boundary have a quantitative difference in thermal characteristics including a thermal expansion coefficient. In addition, the two sides with the reforming layer (110) as the boundary have a structural asymmetry including a thickness difference. Due to at least one of these causes, the two sides with the reforming layer (110) as the boundary are separated without an external force during the cooling process after the temporary substrate bonding step (S400).

It includes separation of both sides with minimal external force, with the reforming layer (110) as the boundary.

Specifically, the seed region (layer) (120) and the seed substrate (100a) are made of the same material, but a nucleation region (101) is formed on the seed region (layer) (120) with the reforming layer (110) as the boundary, and a temporary substrate (300) is bonded to it via the adhesive layer (301).

Therefore, the side including the seed region (layer) (120), the nucleation region (101), the adhesive layer (301), and the temporary substrate (300) with the reforming layer (110) as the boundary, and the side including the seed substrate (100a) have different effective thermal expansion coefficients and effective thermal conductivity that are actually applied due to structural differences.

This is a factor that causes the degree of thermal expansion of the upper and lower sides to differ with respect to the reforming layer (110), and acts as the first factor that separates the seed region (layer) (120) and the seed substrate (100a) without external force with respect to the reforming layer (110).

In addition, there is a difference in thickness between the seed region (layer) (120) and the seed substrate (100a), and a nucleation region (101) is formed on the seed region (layer) (120), and a temporary substrate (300) is bonded via the adhesive layer (301).

Therefore, the internal stresses on both sides of the reforming layer (110) are different. This generates mechanical stress in the reforming layer (110), which is the boundary between the seed region (layer) (120) and the seed substrate (100a), and acts as another factor in separating the seed region (layer) (120) and the seed substrate (100a) without external force, with the reforming layer (110) as the boundary.

The inventor named this separation method ‘hot self-split’.

The above-described ‘hot self-split’ is explained by comparing it with the method using ion implantation.

The method using ion implantation is a method of forcibly injecting hydrogen ions into the inside of the seed substrate to form a reforming layer and then separating the seed region.

The ion implantation technology is based on the technology of accelerating hydrogen ions so that the hydrogen ions can penetrate the target substrate surface and be buried to a specific depth.

Therefore, the surface and inside of the seed substrate along the path of the hydrogen ions cannot avoid damage (implant damage) caused by the hydrogen ions, and a high-temperature annealing process must be performed to recover this damage.

This has the problem of increasing the manufacturing cost as well as the lead time being longer due to the additional process.

In addition, the depth at which the injected hydrogen ions penetrate varies depending on the size of the applied energy and the energy lost due to collision with the surface. Therefore, it is difficult to secure a seed region of uniform quality, and in particular, a follow-up process such as heat treatment is essential when reusing the remaining seed substrate (100) after the seed region is separated.

Next, the embodiment according to the present invention includes a wafer bonding step (S700) of wafer bonding a support substrate (210) to the opposite side of the side where the nucleation region (101) is formed among the two sides of the seed region (layer) (120) separated by the seed region separation step (S500) by a secondary wafer bonding, via a predetermined wafer bonding layer (130).

It is preferable to include a step (S600) of planarizing the side of the two sides of the seed region (layer) (120) where the support substrate (210) is bonded, prior to the wafer bonding step (S700).

The side of the seed substrate (100) generated as a result of the seed region (layer) (120) separation is also planarized for the growth of a new nucleation region.

Thereafter, the manufacturing of an engineered growth substrate for a group III nitride power device in which a nucleation region is formed according to the present embodiment is completed by a temporary substrate removal step (S800) for separating the temporary substrate (300) from the nucleation region (101).

Meanwhile, in the embodiment of the present invention, it is preferable that the temporary substrate (300) is selected to have a thermal expansion coefficient (Effective Thermal Expansion Coefficient) and thermal conductivity (Effective Thermal Conductivity) similar to or the same as the support substrate (210).

In addition, it is more preferable that the crystal structures of the temporary substrate (300) and the support substrate (200) both have a single crystal structure.

This enables excellent bonding of the support substrate (210) and the seed region (layer) (120) in the wafer bonding step (S700).

Meanwhile, the bonding layer (301) of the temporary substrate (300) and the nucleation region (101) may be selected from organic materials (polymers) such as resin, epoxy, SU-8, BCB, etc., which enable the temporary substrate (300) to be easily removed and separated in the subsequent temporary substrate removal step (S800), metals such as Sn, In, Zn, Ga, Au, Ni, Ag, Cu, etc., and ceramic materials such as SiO₂, SiNx, ITO, GaN, InGaN, AlGaN, AlGaInN, ZnO, ZITO, etc.

Next, the wafer bonding layer (130) between the support substrate (210) and the seed region (layer) (120) is formed using a dielectric ceramic material such as SiO₂, SiNx, SOG (Spin-on-Glass), AlN, Al₂O₃, ITO, GaN, InGaN, AlGaN, AlGaInN, ZnO, or ZITO.

For excellent bonding characteristics, it is preferable to form a surface with a surface roughness of less than 1 nm before bonding. Furthermore, surface treatment such as plasma or solution that increases surface energy may be performed.

What is claimed is:

1. The method for manufacturing an engineered growth substrate for a group III-nitride power device in which a nucleation region is formed, comprising:
a seed substrate preparation step of preparing a seed substrate made of single crystal SiC having a set thickness;
a nucleation region forming step of forming a nucleation region on an upper surface of the seed substrate;
a seed substrate reforming step of irradiating the seed substrate with a stealth laser to form a reforming layer parallel to the nucleation region inside the seed substrate;
a temporary substrate bonding step of bonding a temporary substrate to an upper surface of the nucleation region using a predetermined adhesive layer after the seed substrate reforming step; and
a seed region separation step of separating the seed region (layer) on which the nucleation region is formed from the seed substrate with the reforming layer as a boundary.

2. The method of claim 1, wherein further comprises a wafer bonding step of bonding a support substrate to a surface opposite to a surface on which the nucleation region is formed among both sides of the seed region (layer) separated by the seed region separation step via a predetermined wafer bonding layer; and a temporary substrate removing step of separating the temporary substrate from the nucleation region.

3. The method of claim 2, wherein further comprises a step of flattening the surface of the seed region (layer) on which the support substrate is bonded before the wafer bonding step.

4. The method of claim 1, wherein the seed region separation step is characterized in that both sides bordering the reforming layer are separated without an external force due to a structural asymmetry including a quantitative difference in thermal characteristics including a thermal expansion coefficient or a thickness difference.

5. The method of claim 2, wherein the support substrate is characterized in that thermal characteristics including an effective thermal expansion coefficient and an effective thermal conductivity are similar to or identical to those of the seed region (layer).

6. The method of claim 1, wherein the film quality of the nucleation region is equal to or higher than the film quality of epitaxial growth under the same growth conditions on a seed substrate having a thickness that is at least twice the thickness of the seed region (layer), and the film quality includes thickness uniformity or crystal defect density.

7. The method of claim 1, wherein the nucleation region is epitaxial AlN, and the seed region (layer) has a thickness of 50 to 200 μm.

8. The method of claim 6, wherein the crystal defect density includes threading dislocations, inversion domains (IDs), or inversion domain boundaries (IDBs).

9. The method of claim 2, wherein the support substrate is any one of single crystal Si, single crystal SiC, polycrystalline AlN ceramic, and polycrystalline SiC ceramic.

10. The method of claim 1, wherein a positive or negative pattern is formed on the growth surface of the seed substrate where the nucleation region is grown.
